(19) United States
(12) Patent Application Publication
(10) Pub. No.: US 2009/0239363 A1
(43) Pub. Date: Sep. 24, 2009

(54) METHODS FOR FORMING DOPED REGIONS IN SEMICONDUCTOR SUBSTRATES USING NON-CONTACT PRINTING PROCESSES AND DOPANT-COMPRISING INKS FOR FORMING SUCH DOPED REGIONS USING NON-CONTACT PRINTING PROCESSES

(75) Inventors: Roger Yu-Kwan Leung, San Jose, CA (US); De-Ling Zhou, Sunnyvale, CA (US); Wenya Fan, Campbell, CA (US)

Correspondence Address: HONEYWELL INTERNATIONAL INC.;PATENT SERVICES, 101 COLUMBIA ROAD, P O BOX 2245, MORRISTOWN, NJ, 07962-2245, US

(73) Assignee: HONEYWELL INTERNATIONAL, INC., Morristown, NJ (US)

(21) Appl. No.: 12/274,006

(22) Filed: Nov. 19, 2008

Related U.S. Application Data
(63) Continuation-in-part of application No. 12/053,820, filed on Mar. 24, 2008, now abandoned.

(51) Int. Cl. H01L 21/225; C09D 11/00; H01B 1/02

(52) U.S. Cl. 438/562; 106/31.92; 252/521.3; 257/E21.144

(57) ABSTRACT

Methods for forming doped regions in semiconductor substrates using non-contact printing processes and dopant-comprising inks for forming such doped regions using non-contact printing processes are provided. In an exemplary embodiment, a method for forming doped regions in a semiconductor substrate is provided. The method comprises providing an ink comprising a conductivity-determining type dopant, applying the ink to the semiconductor substrate using a non-contact printing process, and subjecting the semiconductor substrate to a thermal treatment such that the conductivity-determining type dopant diffuses into the semiconductor substrate.

### CROSS-REFERENCES TO RELATED APPLICATIONS

This is a continuation-in-part of U.S. application Ser. No. 12/053,820, filed Mar. 24, 2008.

### FIELD OF THE INVENTION

The present invention generally relates to methods for doping regions of semiconductor substrates, and more particularly relates to methods for forming doped regions in semiconductor substrates using non-contact printing processes and dopant-comprising inks for forming such doped regions using non-contact printing processes.

### BACKGROUND OF THE INVENTION

Doping of semiconductor substrates with conductivity-determining type impurities, such as n-type and p-type ions, is used in a variety of applications that require modification of the electrical characteristics of the semiconductor substrates. Well-known methods for performing such doping of semiconductor substrates include photolithography and screen printing. Photolithography requires the use of a mask that is formed and patterned on the semiconductor substrate. Ion implantation then is performed to implant conductivity-determining type ions into the semiconductor substrate. Similarly, screen printing utilizes a patterned screen that is placed on the semiconductor substrate. A screen printing paste containing the conductivity-determining type ions is applied to the semiconductor substrate over the screen so that the paste is deposited on the semiconductor substrate in a pattern that corresponds to the screen pattern. After both methods, a high-temperature anneal is performed to cause the impurity dopants to diffuse into the semiconductor substrate.

In some applications such as, for example, solar cells, it is desirable to dope the semiconductor substrate in a pattern having very fine lines or features. The most common type of solar cell is configured as a large-area p-n junction made from silicon. In one type of such solar cell 10, illustrated in FIG. 1, a silicon wafer 12 having a light-receiving front side 14 and a back side 16 is provided with a basic doping, wherein the basic doping can be of the n-type or of the p-type. The silicon wafer is further doped at one side (in FIG. 1, front side 14) with a dopant of opposite charge of the basic doping, thus forming a p-n junction 18 within the silicon wafer. Photons from light are absorbed by the light-receiving side 14 of the silicon to the p-n junction where charge carriers, i.e., electrons and holes, are separated and conducted to a conductive contact, thus generating electricity. The solar cell is usually provided with metallic contacts 20, 22 on the light-receiving front side as well as on the back side, respectively, to carry away the electric current produced by the solar cell. The metal contacts on the light-receiving front side pose a problem in regard to the degree of efficiency of the solar cell because the metal covering of the front side surface causes shading of the effective area of the solar cell. Although it may be desirable to reduce the metal contacts as much as possible so as to reduce the shading, a metal covering of approximately 10% remains unavoidable since the metallization has to occur in a manner that keeps the electrical losses small. In addition, contact resistance within the silicon adjacent to the electrical contact increases significantly as the size of the metal contact decreases. However, a reduction of the contact resistance is possible by doping the silicon in the narrow areas 24 directly adjacent to the metal contacts on the light-receiving front side 14.

FIG. 2 illustrates another common type of solar cell 30. Solar cell 30 also has a silicon wafer 12 having a light-receiving front side 14 and a back side 16 and is provided with a basic doping, wherein the basic doping can be of the n-type or of the p-type. The light-receiving front side 14 has a rough or textured surface that serves as a light trap, preventing absorbed light from being reflected back out of the solar cell. The metal contacts 32 of the solar cell are formed on the back side 16 of the wafer. The silicon wafer is doped at the backside relative to the metal contacts, thus forming p-n junctions 18 within the silicon wafer. Solar cell 30 has an advantage over solar cell 10 in that all of the metal contacts of the cell are on the back side 16. In this regard, there is no shading of the effective area of the solar cell. However, for all contacts to be formed on the back side 16, the doped regions adjacent to the contacts have to be quite narrow.

As noted above, both solar cell 10 and solar cell 30 benefit from the use of very fine, narrow doped regions formed within a semiconductor substrate. However, the present-day methods of doping described above, that is, photolithography and screen printing, present significant drawbacks. For example, it is prohibitively difficult, if not impossible, to obtain very fine and/or narrow doped regions in a semiconductor substrate using screen printing. In addition, while doping of substrates in fine-lined patterns is possible with photolithography, photolithography is an expensive and time consuming process. In addition, both photolithography and screen printing involve contact with the semiconductor substrate. However, in applications such as solar cells, the semiconductor substrates are becoming very thin. Contact with thin substrates often results in breaking of the substrates. Further, screen printing cannot be used to dope rough or textured surfaces, which are commonly used in solar cell design to trap light within the semiconductor substrate. Moreover, because photolithography and screen printings use custom designed masks and screens, respectively, to dope the semiconductor substrate in a pattern, reconfiguration of the doping pattern is expensive because new masks or screens have to be developed.

Accordingly, it is desirable to provide methods for forming doped regions in semiconductor substrates using non-contact printing processes. In addition, it is desirable to provide dopant-comprising inks for forming such doped regions using non-contact printing processes. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A method for forming doped regions in a semiconductor substrate is provided in accordance with an exemplary embodiment of the present invention. The method comprises the steps of providing an ink comprising a conductivity-determining type dopant, applying the ink to the semiconductor substrate using a non-contact printing process, and subjecting the semiconductor substrate to a thermal treatment such that the conductivity-determining type dopant diffuses into the semiconductor substrate.

A dopant-comprising ink is provided in accordance with an exemplary embodiment of the present invention. The dopant-comprising ink comprises a dopant-silicate carrier and a solvent. The dopant-comprising ink has a spreading factor that is in a range of from about 1.5 to about 6.

A dopant-comprising ink is provided in accordance with another exemplary embodiment of the present invention. The dopant-comprising ink comprises an end-capped dopant-silicate carrier and a solvent.

### BRIEF DESCRIPTION OF THE DRAWINGS

The present invention will hereinafter be described in conjunction with the following drawing figures, wherein like numerals denote like elements, and wherein:

FIG. 1 is a schematic illustration of a conventional solar cell with a light-side contact and a back side contact;

FIG. 2 is a schematic illustration of another conventional solar cell with back side contacts;

FIG. 3 is a cross-sectional view of an inkjet printer nozzle distributing ink on a substrate;

FIG. 4 is a cross-sectional view of an aerosol jet printer mechanism distributing ink on a substrate;

FIG. 5 is a flowchart of a method for forming doped regions in a semiconductor substrate in accordance with an exemplary embodiment of the present invention;

FIG. 6 is a flowchart of a method for formulating a dopant-comprising ink for forming doped regions in a semiconductor substrate using an inkjet printing process, in accordance with an exemplary embodiment of the present invention;

FIG. 7 is an illustration of a portion of a molecular structure of a phosphosilicate carrier formed using the method of FIG. 6;

FIG. 8 is an illustration of a portion of a molecular structure of an end-capped phosphosilicate carrier formed using the method of FIG. 6;

FIG. 9 is an illustration of a portion of a molecular structure of a borosilicate carrier formed using the method of FIG. 6;

FIG. 10 is an illustration of a portion of a molecular structure of an end-capped borosilicate carrier formed using the method of FIG. 6;

FIG. 11 is an illustration of a portion of a molecular structure of a phosphosiloxane carrier formed using the method of FIG. 6;

FIG. 12 is an illustration of a portion of a molecular structure of an end-capped phosphosiloxane carrier formed using the method of FIG. 6;

FIG. 13 is an illustration of a portion of a molecular structure of a borosiloxane carrier formed using the method of FIG. 6; and

FIG. 14 is an illustration of a portion of a molecular structure of an end-capped borosiloxane carrier formed using the method of FIG. 6.

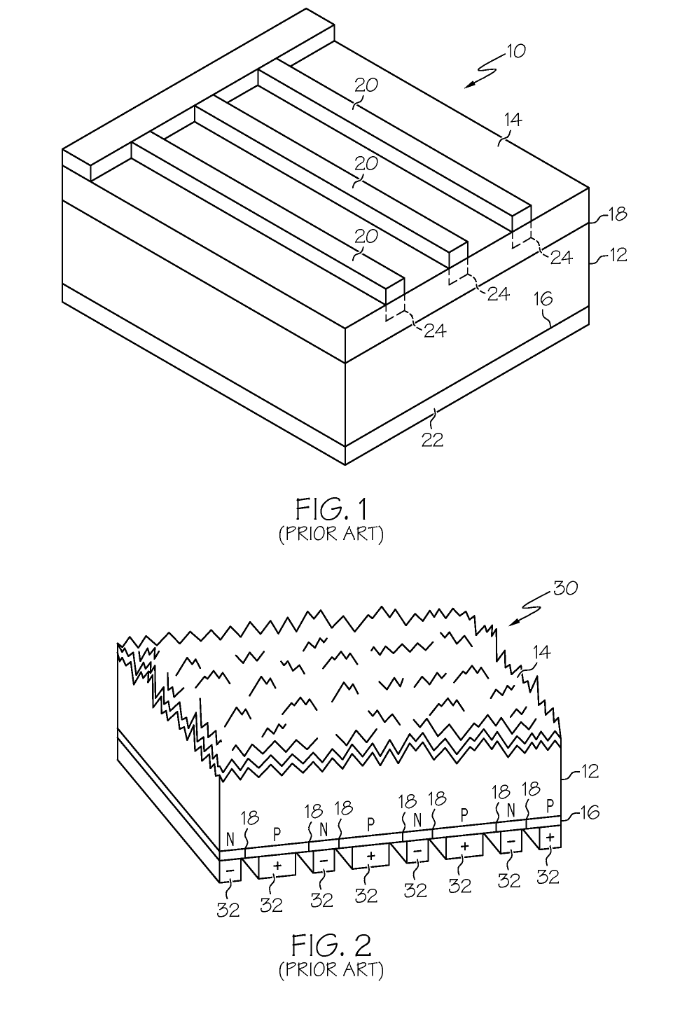

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

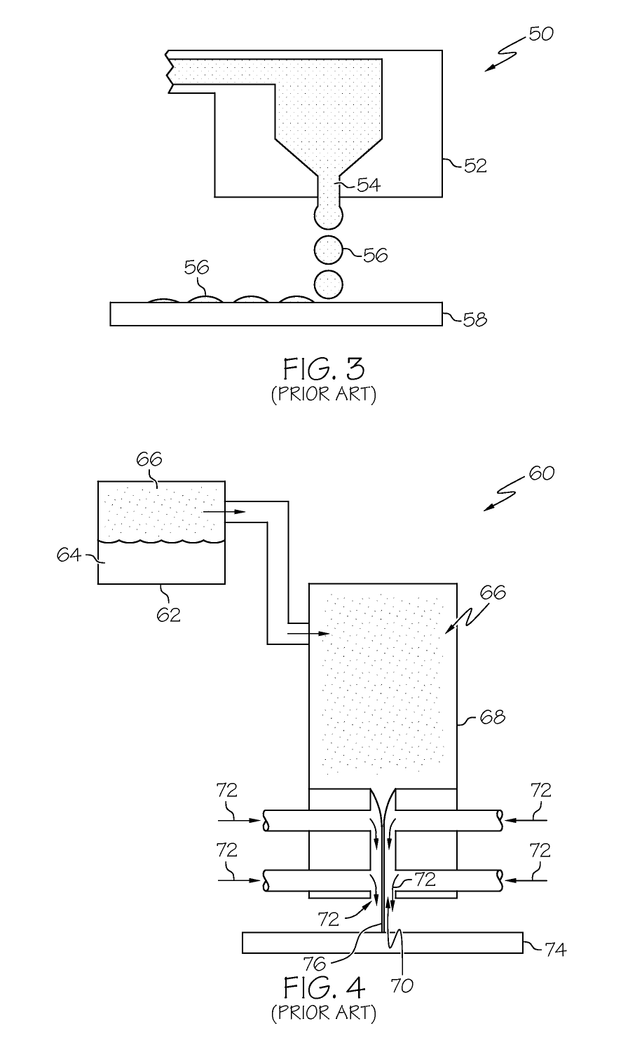

Methods for forming doped regions in semiconductor substrates using non-contact printing processes are provided herein. As used herein, the term “non-contact printing process” means a process for depositing a liquid conductivity-determining type dopant selectively on a semiconductor material in a predetermined patterned without the use of a mask, screen, or other such device. Examples of non-contact printing processes include but are not limited to “inkjet printing” and “aerosol jet printing.” Typically, the terms “inkjet printing,” an “inkjet printing process,” “aerosol jet printing,” and an “aerosol jet printing process” refer to a non-contact printing process whereby a liquid is projected from a nozzle directly onto a substrate to form a desired pattern. In an inkjet printing mechanism 50 of an inkjet printer, as illustrated in FIG. 3, a print head 52 has several tiny nozzles 54, also called jets. As a substrate 58 moves past the print head 52, or as the print head 52 moves past the substrate, the nozzles spray or “jet” ink 56 onto the substrate in tiny drops, forming images of a desired pattern. In an aerosol jet printing mechanism 60, illustrated in FIG. 4, a mist generator or nebulizer 62 atomizes a liquid 64. The atomized fluid 66 is aerodynamically focused using a flow guidance deposition head 68, which creates an annular flow of sheath gas, indicated by arrow 72, to collimate the atomized fluid 66. The co-axial flow exits the flow guidance head 68 through a nozzle 70 directed at the substrate 74 and focuses a stream 76 of the atomized material to as small as a tenth of the size of the nozzle orifice (typically 100 μm). Patterning is accomplished by attaching the substrate to a computer-controlled platen, or by translating the flow guidance head while the substrate position remains fixed.

Such non-contact printing processes are particularly attractive processes for fabricating doped regions in semiconductor substrates for a variety of reasons. First, unlike screen printing or photolithography, only an ink used to form the doped regions touches or contacts the surface of the substrate upon which the ink is applied. Thus, because the breaking of semiconductor substrates could be minimized compared to other known processes, non-contact printing processes are suitable for a variety of substrates, including rigid and flexible substrates. In addition, non-contact printing processes are additive processes, meaning that the ink is applied to the substrate in the desired pattern. Thus, steps for removing material after the printing process, such as is required in photolithography, are eliminated. Further, because non-contact printing processes are additive processes, they are suitable for substrates having smooth, rough, or textured surfaces. Non-contact printing processes also permit the formation of very fine features on semiconductor substrates. In one embodiment, features, such as, for example, lines, dots, rectangles, circles, or other geometric shapes, having at least one dimension of less than about 200 μm can be formed. In another exemplary embodiment, features having at least one dimension of less than about 100 μm can be formed. In a preferred embodiment, features having at least one dimension of less than about 20 μm can be formed. In addition, because non-contact printing processes involve digital computer printers that can be programmed with a selected pattern to be formed on a substrate or that can be provided the pattern from a host computer, no new masks or screens need to be produced when a change in the pattern is desired. All of the above reasons make non-contact printing processes cost-efficient processes for fabricating doped regions in semiconductor substrates, allowing for increased throughput compared to screen printing and photolithography.

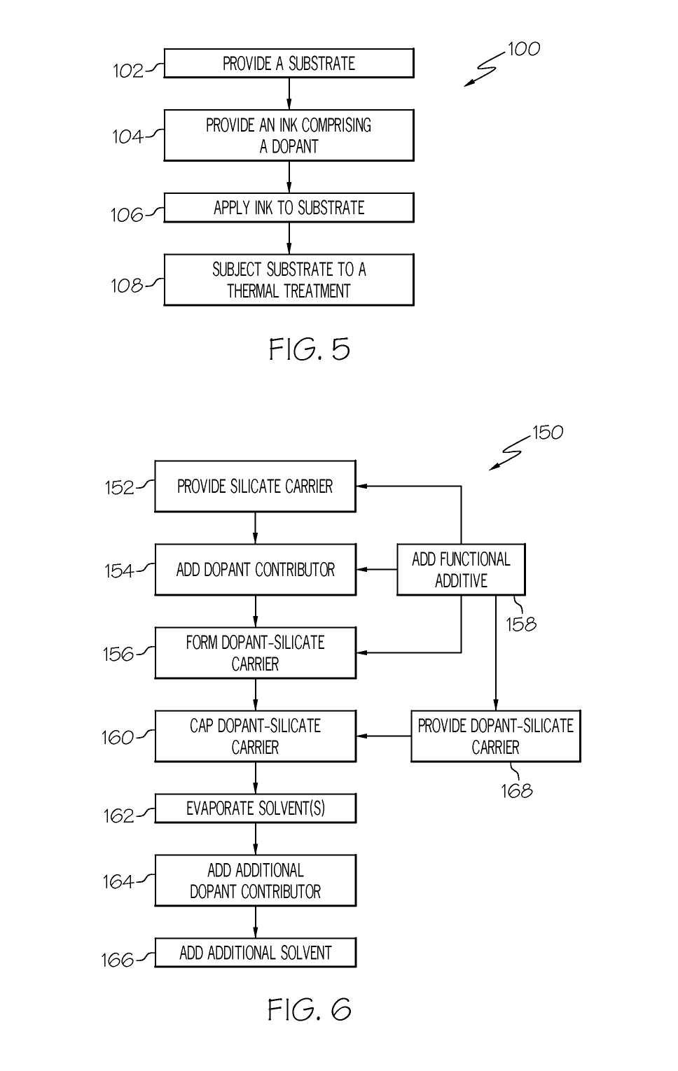

Referring to FIG. 5, a method 100 for forming doped regions in a semiconductor substrate includes the step of providing a semiconductor substrate (step 102). As used herein, the term “semiconductor substrate” will be used to encompass monocrystalline silicon materials, including the relatively pure or lightly impurity-doped monocrystalline silicon materials typically used in the semiconductor industry, as well as polycrystalline silicon materials, and silicon admixed with other elements such as germanium, carbon, and the like. In addition, “semiconductor substrate” encompasses other semiconductor materials such as relatively pure and impurity-doped germanium, gallium arsenide, and the like. In this regard, the method 100 can be used to fabricate a variety semiconductor devices including, but not limited to, microelectronics, solar cells, displays, RFID components, microelectromechanical systems (MEMS) devices, optical devices such as microlenses, medical devices, and the like.

The method 100 further includes the step of providing a conductivity-determining type impurity dopant-comprising ink (hereinafter, a “dopant-comprising ink”) (step 104), which step may be performed before, during or after the step of providing the semiconductor substrate. A method for fabricating a dopant-comprising ink is described in more detail in reference to FIG. 6, discussed below. In accordance with an exemplary embodiment of the present invention, the dopant-comprising ink comprises the appropriate conductivity-determining type impurity dopant that is required for the doping. For example, for forming n-type doped regions, the ink comprises a substance comprising phosphorous, arsenic, antimony, or combinations thereof. For forming p-type doped regions, the ink comprises a boron-containing substance. The dopant-comprising ink should meet at least one of several performance criteria for inkjet printing. First, the ink is formulated so that it can be printed to form fine or small features, such as lines, dots, circles, squares, or other geometric shapes. In one exemplary embodiment of the invention, the ink is formulated so that features having at least one dimension of less than about 200 μm can be printed. In another exemplary embodiment of the invention, the ink is formulated so that features having at least one dimension less than about 100 μm can be printed. In a preferred embodiment of the present invention, the ink is formulated so that features having a dimension of less than about 20 μm can be printed. Second, during the printing process and during pausing of the printing process, the ink results in minimal, if any, clogging of the printer nozzles. Clogging of the nozzles results in down-time of the printer, thus reducing throughput. In one exemplary embodiment, the dopant-comprising ink has a viscosity in the range of about 1.5 to about 50 centipoise (cp). Further, the ink is formulated so that, after it is deposited on the substrate and high-temperature annealing (discussed in more detail below) is performed, the resulting doped region has a sheet resistance in the range of about 10 to about 100 ohms/square (Ω/sq.). Moreover, the ink is formulated so that the dopant and/or the dopant-comprising ink do not significantly diffuse from the penned area, that is, the area upon which the ink is deposited, into unpenned areas before the high temperature anneal is performed. Significant diffusion of the dopant and/or the dopant-comprising ink from the penned area, either by vapor transport or by diffusion through the substrate, before annealing at the proper annealing temperature may significantly adversely affect the electrical properties of devices comprising the resulting doped regions. The dopant-comprising ink also is formulated so that significant diffusion of the dopant from the penned area into unpenned areas during the annealing process is minimized or prevented altogether. In other words, localized doping, in contrast to blanket doping, is desirably effected. Significant diffusion of the dopant from the penned area into unpenned areas, either by vapor transport or by diffusion through the substrate during the annealing process, should be minimized or eliminated so as to achieve localized doping without significantly changing the dopant distribution outside of the penned area.

The dopant-comprising ink is applied overlying the substrate using a non-contact printer (step 106). As used herein, the term “overlying” encompasses the terms “on” and “over”. Accordingly, the dopant-comprising ink can be applied directly onto the substrate or may be deposited over the substrate such that one or more other materials are interposed between the ink and the substrate. Examples of materials that may be interposed between the dopant-comprising ink and the substrate are those materials that do not obstruct diffusion of the ink into the substrate during annealing. Such materials include phosphosilicate glass or borosilicate glass that forms on a silicon material during formation of P-well regions or N-well regions therein. Typically such silicate glass materials are removed by deglazing before dopants are deposited on the silicon material; however, in various embodiments, it may be preferable to omit the deglazing process, thereby permitting the silicate glass to remain on the substrate.

The dopant-comprising ink is applied to the substrate in a pattern that is stored in or otherwise supplied to the non-contact printer. An example of an inkjet printer suitable for use includes, but is not limited to, Dimatix Inkjet Printer Model DMP 2811 available from Fujifilm Dimatix, Inc. of Santa Clara, Calif. An example of an aerosol jet printer suitable for use includes, but is not limited to, an M3D Aerosol Jet Deposition System available from Optomec, Inc., of Albuquerque, N.M. Preferably, the ink is applied to the substrate at a temperature in the range of about 15° C. to about 80° C. in a humidity of about 20 to about 80%. Once the pattern of dopant-comprising ink is formed on the substrate, the substrate is subjected to a high-temperature thermal treatment or “anneal” to cause the dopant of the dopant-comprising ink to diffuse into the substrate, thus forming doped regions within the substrate in a predetermined or desired manner (step 108). The time duration and the temperature of the anneal is determined by such factors as the initial dopant concentration of the dopant-comprising ink, the thickness of the ink deposit, the desired concentration of the resulting dopant region, and the depth to which the dopant is to diffuse. The anneal can be performed using any suitable heat-generating method, such as, for example, infrared heating, laser heating, microwave heating, and the like. In one exemplary embodiment of the present invention, the substrate is placed inside an oven wherein the temperature is ramped up to a temperature in the range of about 850° C. to about 1100° C. and the substrate is baked at this temperature for about 2 to about 90 minutes. Annealing also may be carried out in an in-line furnace to increase throughput. The annealing atmosphere may contain 0 to 100% oxygen in an oxygen/nitrogen or oxygen/argon mixture. In a preferred embodiment, the substrate is subjected to an anneal temperature of about 1050° C. for about ten (10) minutes in an oxygen ambient.

Referring to FIG. 6, in accordance with one exemplary embodiment of the present invention, a method 150 for fabricating a dopant-comprising ink, such as the dopant comprising ink used in the method 100 of FIG. 5, includes the step of providing a silicate carrier (step 152). As described in more detail below, the silicate carrier will serve as the carrier of the impurity dopant of the dopant-comprising ink. The terms “silicate” and “silicate carrier” are used herein to encompass silicon- and oxygen-containing compounds including, but not limited to, silicates, including organosilicates, siloxanes, silsesquioxanes, and the like. In one exemplary embodiment, suitable silicate carriers include commercially available silicate carriers such as, for example, USG-50, 103AS, 203AS, T30 and T111, all available from Honeywell International of Morristown, N.J. In another exemplary embodiment, a silicate carrier may be formed by combining at least one hydrolysable silane with at least one hydrogen ion contributor to undergo hydrolysis and polycondensation in a sol-gel reaction to form the silicate carrier. Preferably, the hydrolysable silane, or mixture of hydrolysable silanes, is selected so that the carbon content of the resulting dopant-silicate carrier, with or without end-capping, as discussed in more detail below, is in the range of 0 to about 25 weight percent (wt. %). A carbon content in this range is sufficiently high that it may improve shelf-life of the dopant-comprising ink and minimize nozzle clogging but is sufficiently low so as not to inhibit deglazing of the ink from the substrate after anneal. Suitable hydrolysable silanes include those having the formula R¹ₘSiR²ₙ, where R¹ is hydrogen or an alkyl or aryl group, R² is an alkoxy, acetoxy, or chloro group, n is a number between 1 and 4, and m=4−n. Examples of hydrolysable silanes suitable for use in forming the silicate carrier include, but are not limited to, chlorosilane, methylchlorosilane, tetralkoxysilanes such as, for example, tetraethylorthosilicate (TEOS), tetramethoxysilane, and tetraacetoxysilane, alkyltrialkoxysilanes such as, for example, methyltrimethoxysilane, dialkyldialkoxysilanes such as dimethyldimethoxysilane, and the like, and combinations thereof. Examples of hydrogen ion contributors include water, preferably de-ionized water, and methanol. The sol-gel reaction is catalyzed by the addition of either an acid or base, such as, for example, nitric acid, acetic acid, ammonium hydroxide, and the like.

In one exemplary embodiment, the silicate carrier is formed in a solvent in which the silicate sol-gel is soluble. The presence of a solvent during formation of the silicate carrier allows for slowing and/or controlling of the polymerization of the sol-gel. Solvents suitable for use comprise any suitable pure fluid or mixture of fluids that is capable of forming a solution with the silicate sol-gel and that may be volatilized at a desired temperature. In some contemplated embodiments, the solvent or solvent mixture comprises aliphatic, cyclic, and aromatic hydrocarbons. Aliphatic hydrocarbon solvents may comprise both straight-chain compounds and compounds that are branched. Cyclic hydrocarbon solvents are those solvents that comprise at least three carbon atoms oriented in a ring structure with properties similar to aliphatic hydrocarbon solvents. Aromatic hydrocarbon solvents are those solvents that comprise generally benzene or naphthalene structures. Contemplated hydrocarbon solvents include toluene, xylene, p-xylene, m-xylene, mesitylene, solvent naphtha H, solvent naphtha A, alkanes, such as pentane, hexane, isohexane, heptane, nonane, octane, dodecane, 2-methylbutane, hexadecane, tridecane, pentadecane, cyclopentane, 2,2,4-trimethylpentane, petroleum ethers, halogenated hydrocarbons, such as chlorinated hydrocarbons, nitrated hydrocarbons, benzene, 1,2-dimethylbenzene, 1,2,4-trimethylbenzene, mineral spirits, kerosene, isobutylbenzene, methylnaphthalene, ethyltoluene, and ligroine.

In other contemplated embodiments, the solvent or solvent mixture may comprise those solvents that are not considered part of the hydrocarbon solvent family of compounds, such as alcohols, ketones (such as acetone, diethylketone, methylethylketone, and the like), esters, ethers, amides and amines. Examples of solvents suitable for use during formation of the silicate carrier include alcohols, such as methanol, ethanol, propanol, butanol, and pentanol, anhydrides, such as acetic anhydride, and other solvents such as propylene glycol monoether acetate and ethyl lactate, and mixtures thereof.

The hydrolysable silane, the hydrogen ion contributor, any present solvents, and any other additives are mixed using any suitable mixing or stirring process that forms a homogeneous sol-gel mixture. For example, a reflux condenser, a low speed sonicator or a high shear mixing apparatus, such as a homogenizer, a microfluidizer, a cowls blade high shear mixer, an automated media mill, or a ball mill, may be used for several seconds to an hour or more to form the silicate carrier. Heat also may be used to facilitate formation of the silicate carrier, although the heating should be undertaken at conditions that avoid substantial vaporization of the solvent(s), that is, at conditions that avoid evaporation of more than about 10 weight percent of the solvent. In a preferred embodiment of the present invention, the silicate carrier is formed at a temperature in the range of about 15° C. to about 160° C.

In one exemplary embodiment of the invention, the dopant-comprising ink is formulated so that spreading of the ink when penned onto the substrate is minimized. In a preferred embodiment of the invention, the dopant-comprising ink has a spreading factor in the range of from about 1.5 to about 6. The term “spreading factor” of a non-contact printing process ink is defined in terms of an inkjet printing process and is the ratio of the average diameter of a dot of the ink deposited by a nozzle of an inkjet printer to the diameter of the nozzle when the semiconductor substrate is at a temperature in a range of from 50° C. to about 60° C., the temperature of the ink at the nozzle is in a range of about 20° C. to about 22° C., the distance between the tip of the nozzle proximate to the substrate and the substrate is about 1.5 millimeters (mm) and the jetting frequency, that is, the number of ink drops jetted from the nozzle per second, is 2 kilohertz (kHz). By minimizing the spreading of the ink on the substrate, fine features, such as those described above having at least one feature that is less than about 200 μm or smaller, can be achieved. In this regard, in one embodiment of the invention, the silicate carrier and/or the solvent or solvent mixture are selected so that the resulting dopant-comprising ink has a spreading factor in the range of from about 1.5 to about 6.

In an optional exemplary embodiment of the invention, a functional additive may be added to the silicate carrier (step 158), that is, during or after formation of the silicate carrier. In one exemplary embodiment, a spread-minimizing additive is added. The spread-minimizing additive is an additive that modifies the surface tension, viscosity, and/or wettability of the dopant-comprising ink so that spreading of the ink when penned onto the substrate is minimized. As used herein, the term “spread-minimizing additive” refers to such an additive that reduces the spreading factor of the dopant-comprising ink to a range of from about 1.5 to about 6. Examples of spread-minimizing additives include, but are not limited to, iso-stearic acid, polypropylene oxide (PPO), such as polypropylene oxide having a molecular weight of 4000 (PPO4000), vinylmethylsiloxane-dimethylsiloxane copolymer, such as VDT131 available form Gelest, Inc. of Tullytown, Pa., polyether-modified polysiloxanes, such as Tegophren 5863 available from Evonik Degussa GmbH of Essen, Germany, other organo-modified polysiloxanes, such as Tegoglide 420 also available from Evonik Degussa GmbH, and the like, and combinations thereof.

In addition, it also is desirable to minimize the drying rate of the resulting dopant-comprising ink to minimize or eliminate clogging of the printer nozzles, such as nozzles having dimensions as small as 10 nm. Thus, in another exemplary embodiment, a functional additive such as a solvent with a high boiling point, that is, in the range of from about 50° C. to about 250° C., such as, for example, glycerol, may be added to increase the boiling point of the resulting dopant-comprising ink and minimize the drying rate of the ink. In a preferred embodiment, the silicate sol-gel is soluble in the high boiling point solvent. Examples of solvents with high boiling points suitable for use include glycerol, propylene glycol, iso-stearic acid, propylene glycol butyl ether, ethylene glycol, and the like, and combinations thereof.

It also may be desirable to minimize the amount of the resulting dopant-silicate carrier that diffuses beyond the penned area into unpenned areas of the substrate before the predetermined annealing temperature of the annealing process is reached. As noted above, diffusion of the dopant-silicate carrier beyond the penned area into unpenned areas before annealing can significantly affect the electrical characteristics of the resulting semiconductor device that utilizes the subsequently-formed doped region. Thus, in a further exemplary embodiment, a functional additive such as a viscosity modifier that minimizes or prevents such diffusion may be added. Preferably, the resulting dopant-silicate carrier, described in more detail below, is soluble in the viscosity modifier. Examples of such viscosity-modifiers include glycerol, polyethylene glycol, polypropylene glycol, ethylene glycol/propylene glycol copolymer, organo-modified siloxanes, ethylene glycol/siloxane copolymers, polyelectrolyte, and the like, and combinations thereof. Examples of other suitable additives that may be added to the silicate carrier include dispersants, surfactants, polymerization inhibitors, wetting agents, antifoaming agents, detergents and other surface-tension modifiers, flame retardants, pigments, plasticizers, thickeners, viscosity modifiers, rheoloy modifiers, and mixtures thereof. It will be appreciated that a functional additive may serve one or more functions. For example, a spread-minimizing additive may also serve as a high-boiling point solvent, and/or a high boiling point solvent may serve as a viscosity modifier.

The method 150 further includes the step of adding a dopant contributor (step 154). The dopant contributor, as described in more detail below, will be the source of the conductivity-determining type impurity dopants that will bond with or be dispersed within the silicate carrier, thus forming a dopant-silicate carrier. In one exemplary embodiment, the dopant contributor is added directly to the silicate carrier. Boron contributors suitable for use in method 150 include boric acid, boron oxide, boron tribromide, boron triiodide, triethylborate, tripropylborate, tributylborate, trimethylborate, tri(trimethylsilyl)borate, and the like, and combinations thereof. Suitable phosphorous contributors include phosphorous oxides, such as phosphorous pentoxide, phosphoric acid, phosphorous acid, phosphorus tribromide, phosphorus triiodide, and the like, and combinations thereof. In another exemplary embodiment, at least one dopant contributor is mixed with a solvent or mixture of solvents in which the dopant contributor is soluble before addition to the silicate carrier. Suitable solvents include any of the solvents described above for fabricating the silicate carrier. In an optional embodiment, functional additives, such as any of the functional additives described above, may be added to the dopant contributor and/or the solvent (step 158). If used, the solvent and any functional additives can be mixed with the dopant contributor using any suitable mixing or stirring process described above. Heat also may be used to facilitate mixing, although the heating should be undertaken at conditions that avoid substantial vaporization of the solvent(s). In a preferred embodiment of the present invention, the dopant contributor is mixed with at least one solvent and/or functional additive at a temperature in the range of about 15° C. to about 180° C.

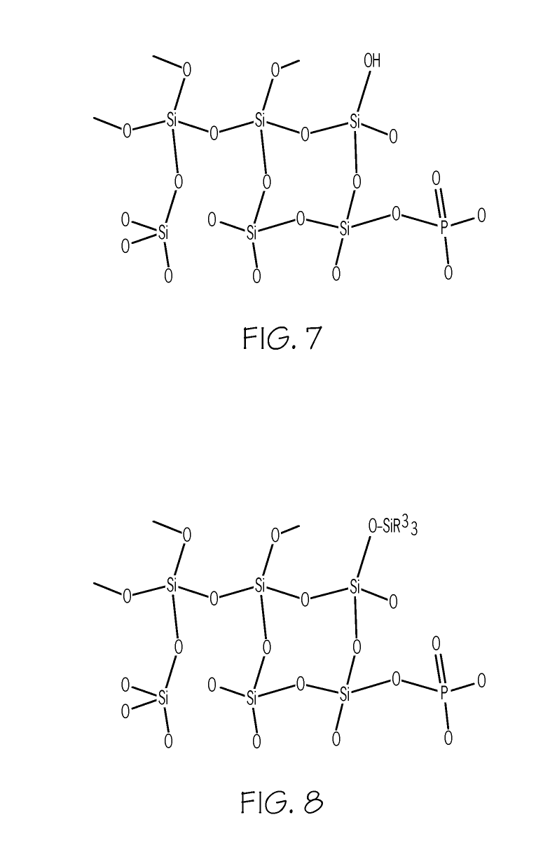

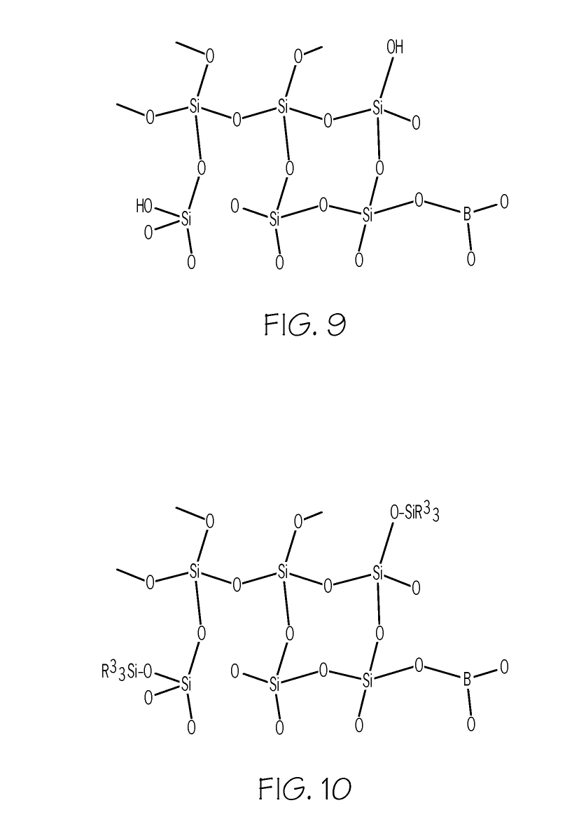

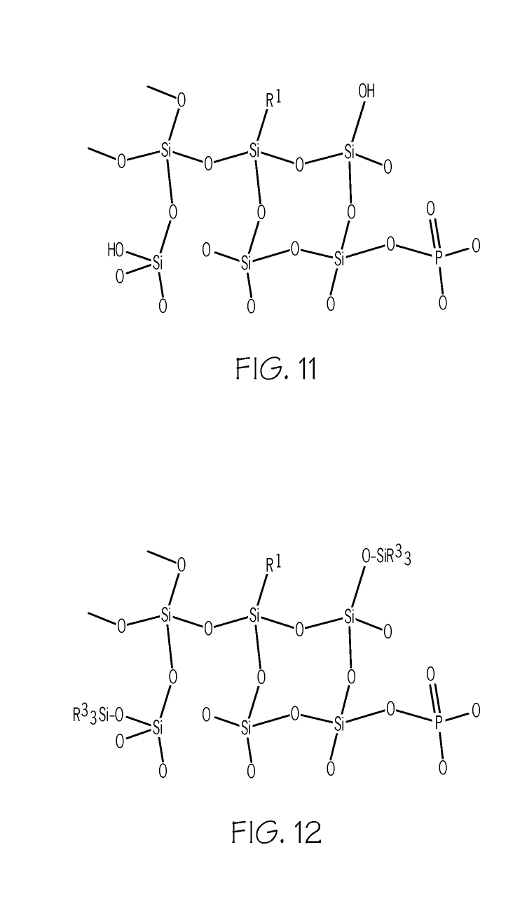

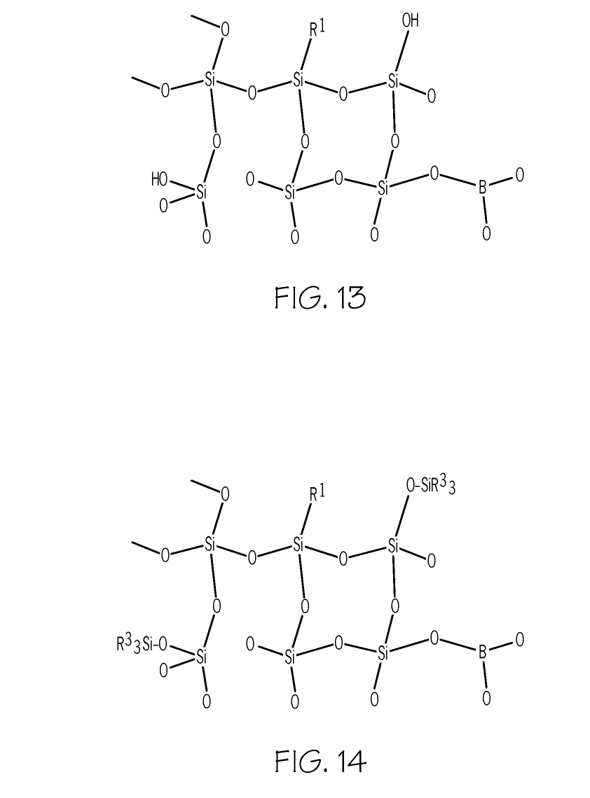

The method continues with the step of combining the silicate carrier and the dopant contributor, with or without having been previously combined with a solvent and/or functional additive, to form a dopant-silicate carrier (step 156). The dopant-silicate carrier has a silicon-oxygen backbone structure, as shown in FIGS. 7, 9, 11 and 13. FIG. 7 illustrates a portion of the molecular structure of an exemplary phosphorous-silicate carrier (a “phosphosilicate”) formed as described above, FIG. 9 illustrates a portion of the molecular structure of an exemplary boron-silicate carrier (a “borosilicate”) formed as described above, FIG. 11 illustrates a portion of the molecular structure of another exemplary phosphorous-silicate carrier (a “phosphosiloxane”) formed as described above, where R¹ is hydrogen, an alkyl or an aryl group, and FIG. 13 illustrates a portion of the molecular structure of another exemplary boron-silicate carrier (a “borosiloxane”) formed as described above, where R¹ is hydrogen, an alkyl or an aryl group. In an exemplary embodiment, solvent also is added to facilitate formation of the dopant-silicate carrier. Any of the above-described solvents may be used. In an optional embodiment, functional additives, such as any of the functional additives described above, also may be added (step 158). The silicate carrier, the dopant source, any present solvents, and any present functional additives are mixed using any suitable mixing or stirring process that forms a homogeneous dopant-silicate carrier mixture, such as any of the mixing or stirring methods described above. Heat also may be used to facilitate formation of the dopant-silicate carrier of the dopant-silicate carrier mixture. In a preferred embodiment of the present invention, the dopant-silicate carrier is formed at a temperature in the range of about 15° C. to about 160° C. While the method 150 of FIG. 6 illustrates that the silicate carrier is provided first (step 152) and then the dopant contributor is added to the silicate carrier (step 154) to form the dopant-silicate carrier (step 156), it will be understood that components of the silicate carrier and the dopant contributor may be added together to form the dopant-silicate carrier, thus combining steps 152, 154, and 156.

In an alternative embodiment of the present invention, rather than forming a dopant-silicate carrier pursuant to steps 152, 154, and 156 described above, method 150 includes the step of providing a commercially-available dopant-silicate carrier (step 168). Commercially-available dopant-silicate carriers include, but are not limited to, borosilicates such as Accuspin B-30, Accuspin B-40, and Accuspin B-60, and phosphosilicates such as Accuspin P-8545, Accuspin P-854 2:1, Accuglass P-TTY (P-112A, P-112 LS, and P-114A), and Accuglass P-5S, all available from Honeywell International. The dopant-silicate carrier can be combined with one or more solvents, such as any of the solvents described above with reference to step 152 of FIG. 6. In another exemplary embodiment of the invention, a spread-minimizing additive is added to the commercially-available dopant-silicate carrier. In a further, optional, embodiment, functional additives, such as any of the functional additives described previously, also may be added (step 158).

Referring back to FIG. 6, in accordance with another exemplary embodiment, the dopant-silicate carrier is end-capped using a capping agent (step 160). End-capping replaces the unreacted condensable (cross-linkable) group (e.g., —H or —R, where R is a methyl, ethyl, acetyl, or other alkyl group) of the dopant-silicate carrier with a non-condensable (non-cross-linkable) alkylsilyl group or arylsilyl group (—SiR³₃), where R³ comprises one or more of the same or different alkyl and/or aryl groups, to become —OSiR³₃, thus reducing or, preferably, preventing gelation of the dopant-silicate carrier. In this regard, clogging of printer nozzles and print heads due to gelation of the dopant-silicate carrier is minimized or eliminated. FIGS. 8, 10, 12, and 14 illustrate the dopant-silicate carriers of FIGS. 7, 9, 11, and 13, respectively, with end-capping. As noted above, the total carbon content of the resulting end-capped dopant-silicate carrier is in the range of about 0 to about 25 wt. %. The carbon content of the dopant-silicate carrier includes carbon components from end-capping group R³ and from mid-chain group R¹. Suitable capping agents include acetoxytrimethylsilane, chlorotrimethylsilane, methoxytrimethylsilane, trimethylethoxysilane, triethylsilanol, triethylethoxysilane, and the like, and combinations thereof. The degree of end-capping is dependent on the doped-silicate carrier polymer size, the nozzle diameter, and the printing requirements. Preferably, the weight percent of the end-capping group of the end-capped dopant-silicate carrier is about 0 to about 10% of the dopant-silicate carrier. In a more preferred embodiment, the weight percent of the end-capping group of the end-capped dopant-silicate carrier is no greater than about 1% of the dopant-silicate carrier.

In accordance with yet another exemplary embodiment of the present invention, if the dopant-silicate carrier is present in excess solvent, the dopant-silicate carrier mixture is concentrated by at least partial evaporation of the solvent or solvent mixture (step 162). In this regard, the concentration and viscosity of the resulting dopant-comprising ink can be controlled and increased. In an exemplary embodiment of the invention, at least about 10% of the solvent(s) is evaporated. The solvent(s) may be evaporated using any suitable method such as, for example, permitting evaporation at or below room temperature, or heating the dopant-silicate carrier mixture to temperatures at or above the boiling points of the solvent(s). While FIG. 6 illustrates method 150 with the step of evaporating the solvent (step 162) performed after the step of end-capping the dopant-silicate carrier (step 160), it will be understood that step 162 can be performed before step 160.

In another, optional, embodiment of the present invention, at least one additional dopant contributor is added to the dopant-silicate carrier to increase the dopant concentration (step 164). The additional dopant contributor may comprise the dopant contributor or contributors described above with reference to step 154 or may comprise other dopant contributors.

Additional solvent also may be added to the dopant-silicate carrier mixture (step 166). In this regard, the wettability and fluidity of the mixture can be increased to decrease the viscosity, thus decreasing the possibility of clogging the nozzles of the inkjet printer heads. Any additional functional additives, such as those described above, also may be added at this time.

The following are examples of dopant-comprising inks for use in fabricating doped regions of semiconductor substrates using non-contact printing processes. The examples are provided for illustration purposes only and are not meant to limit the various embodiments of the present invention in any way.

### EXAMPLE 1

About 440 gm B30 borosilicate, available from Honeywell International, was mixed with 44 gm acetoxytrimethylsilane and left at room temperature for about three hours to form an end-capped boron silicate ink. The end-capped borosilicate ink then was concentrated by distilling off about 363 gm solvent in a rotary evaporator while keeping the solution at a temperature below 23° C. The final weight of the end-capped boron silicate ink was 121 gm. About 17.9 gm of the end-capped boron silicate ink was mixed with 17.9 gm ethanol to increase the fluidity of the ink. A final end-capped boron silicate ink was prepared by adding 0.58 gm boric acid to 35.8 gm of the mixture, stirring to dissolve the boric acid, and then filtering using a 0.2 μm nylon filter. The composition of the final end-capped boron silicate ink was 49.2 wt. % end-capped boron silicate ink, 49.2 wt. % ethanol, and 1.6 wt. % boric acid. The viscosity was about 3.5 cp at 21° C.

### EXAMPLE 2

About 20 gm of Accuspin B-30 borosilicate was mixed with 2 gm acetoxytrimethylsilane and 2.2 gm vinylmethylsiloxane-dimethylsiloxane copolymer (VDT131, available form Gelest, Inc. of Tullytown, Pa.) and left at room temperature for about four hours to form an end-capped boron silicate ink. The ink then was filtered using a 0.2 μm nylon filter. The viscosity was about 2.0 cp. at 21° C.

### EXAMPLE 3

About 44 gm Accuspin B-30 was subjected to rotary evaporation to obtain 21.9 gm concentrated ink. The concentrated ink was then filtered using a 0.2 μm nylon filter. A final ink of 96.2 wt. % of the filtered ink, 1.3 wt. % acetoxytrimethylsilane, and 2.5 wt. % VDT131 was prepared. The viscosity of the final ink was about 3.3 cp.

### EXAMPLE 4

About 30 gm Accuspin B-30 was mixed with 2.5 gm ethoxytrimethylsilane and 16.2 gm isostearic acid and left at room temperature for about sixteen (16) hours to form an end-capped boron silicate ink solution. The solution then was concentrated by distilling off about 12.2 gm solvent in a rotary evaporator while keeping the solution at a temperature below 23° C. The viscosity of the concentrated ink was about 9.2 cp. About 10 gm ethanol was added to about 5 gm of the concentrated ink. The viscosity of the final ink was 4.1 cp.

### EXAMPLE 5

A boron-comprising ink was formed comprising about 71.5 wt. % Accuspin B-30 and 28.5 wt. % polypropylene glycol (molecular weight of about 4000).

### EXAMPLE 6

A boron-comprising ink was formed comprising about 89.5 wt. % Accuspin B-30, 8.1 wt. % methoxytrimethylsilane, 6.2 wt. % VDT131, and 2.1 wt. % boric acid.

### EXAMPLE 7

About 440 gm Accuspin B-30 was mixed with 44 gm acetoxytrimethylsilane and left at room temperature for about three hours to form an end-capped boron silicate ink. The diluted ink then was concentrated by distilling off about 363 gm in rotary evaporator while keeping the solution at a temperature below 23° C. The final weight of the concentrated end-capped boron silicate ink was 121 gm. About 35.63 gm of the concentrated end-capped boron silicate ink was mixed with 21.45 gm ethanol. The viscosity was about 4.5 cp.

### EXAMPLE 8

About 30 gm P 8545, available from Honeywell International, was mixed with 3 gm acetoxytrimethylsilane to form an end-capped phosphorous-comprising ink.

### EXAMPLE 9

About 30 gm Accuglass P-5 phosphosilicate, available from Honeywell International, was mixed with about 0.9 gm acetoxytrimethylsilane to form an end-capped phosphorous-comprising ink.

### EXAMPLE 10

A Fujifilm Dimatix Inkjet Printer Model DMP 2811 was used to print patterns using the end-capped boron-comprising ink of Example 1. The ink was jetted continuously from both a 21 um and a 9 um nozzle printhead without clogging. A 2 cm×6 cm rectangle was printed onto an n-type wafer. After printing, the printed wafer was heated to 1050° C. and held at 1050° C. for 10 minutes. The printed area was marked by scribing and then immersed in 20:1 DHF solution for 10 minutes for deglazing. After deglazing, the wafer was clear of film and residue. Sheet resistance was measured using 4-point probe. The resistance of the printed area was 20 ohm/sq. whereas the sheet resistance of the non-print area was greater than 5000 ohm/sq. An array of narrow lines with dimensions of 45 μm by 2 cm and an array of circles having diameters of about 36 μm also were printed on an n-type wafer using a Fujifilm Dimatix Inkjet Printer Model DMP2811 having nozzles of about 1 pL. The nozzles were jetted for 8 hours without clogging.

### EXAMPLE 11

Approximately 100 parts of the end-capped boron-comprising ink formed according to the method of Example 1 were mixed with the following additives in amounts as set forth below. The resulting inks were jetted onto an n-type polished wafer through a 21 μm nozzle of a Fujifilm Dimatix Inkjet Printer Model DMP 2811 having a dispense volume of 10 pL. The inkjet printer stage was heated to about 55° C. and the inks were jetted from the nozzle at a temperature of about 20-22° C. and a frequency of about 2 kHz. The bottom tip of the nozzle was approximately 1.5 mm from the substrate. An array of dots was printed on the wafer and the dot diameter was measured. The spread factor results are set forth in the following Table 1:

TABLE 1

| Amount of Ink | | Amount of | Average | Spread |
|---|---|---|---|---|
| from Example 1 | Modifier | Modifier | Dot Size | Factor |
| 100 parts | None | none | 65 μm | 3.1 |
| 100 parts | Tegoglide 420 | 5.9 parts | 48 μm | 2.3 |
| 100 parts | Tegophren 5863 | 5.4 parts | 49 μm | 2.4 |
| 100 parts | PPO4000 | 11.3 parts | 38 μm | 1.8 |

### EXAMPLE 12

Approximately 100 parts of the end-capped boron-comprising ink formed according to the method of Example 1 were mixed with the following additives in amounts as set forth below. The resulting inks were jetted on an n-type polished wafer through a 9 μm nozzle of a Fujifilm Dimatix Inkjet Printer Model DMP 2811 having a dispense volume of 1 pL. The inkjet printer stage was heated to about 50° C.-52° C. and the inks were jetted from the nozzle at a temperature of about 20-22° C. and at a frequency of about 2 kHz. The bottom tip of the nozzle was approximately 1.5 mm from the substrate. An array of dots was printed on the wafer and the dot diameter was measured. The spread factor results are set forth in the following Table 2:

TABLE 2

| Amount of Ink | | Amount of | Average Dot | Spread |
|---|---|---|---|---|
| from Example 1 | Modifier | Modifier | Size | Factor |
| 100 parts | None | none | 45 μm | 5 |
| 100 parts | Tegophren 5863 | 5.4 parts | 30 μm | 3.3 |
| 100 parts | Tegophren 5863 | 11.1 parts | 25 μm | 2.8 |

Accordingly, methods for forming doped regions in semiconductor substrates using non-contact printing processes and dopant-comprising inks for forming such doped regions using non-contact printing processes have been provided. While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for forming doped regions in a semiconductor substrate, the method comprising the steps of:
providing an ink comprising a conductivity-determining type dopant;
applying the ink to the semiconductor substrate using a non-contact printing process; and
subjecting the semiconductor substrate to a thermal treatment such that the conductivity-determining type dopant diffuses into the semiconductor substrate.

2. The method of claim 1, wherein the step of providing an ink comprises the step of providing an ink comprising a dopant-silicate carrier, a spread-minimizing additive that results in a spreading factor of the ink that is in a range of from about 1.5 to about 6, and a solvent.

3. The method of claim 2, wherein the step of providing an ink comprises the step of providing an ink comprising a boron-silicate carrier, the spread-minimizing additive, and the solvent.

4. The method of claim 2, wherein the step of providing an ink comprises the step of providing an ink comprising a phosphorous-silicate carrier, the spread-minimizing additive, and the solvent.

5. The method of claim 2, wherein the step of providing an ink comprises the step of providing an ink comprising the dopant-silicate carrier, the solvent, and the spread-minimizing additive comprising an additive selected from the group consisting of isostearic acid, polypropylene oxide, vinylmethylsiloxane-dimethylsiloxane copolymer, polyether-modified polysiloxanes, organo-modified polysiloxanes, and combinations thereof.

6. The method of claim 1, wherein the step of providing an ink comprises the step of providing an ink comprising an end-capped dopant-silicate carrier and a solvent.

7. The method of claim 6, wherein the step of providing an ink comprises the step of providing an ink comprising an end-capped boron-silicate carrier.

8. The method of claim 6, wherein the step of providing an ink comprises the step of providing an ink comprising an end-capped phosphorous-silicate carrier.

9. The method of claim 6, wherein the step of providing an ink comprises the step of providing an ink that has a spread-minimizing additive comprising a material selected from the group consisting of isostearic acid, polypropylene oxide, vinylmethylsiloxane-dimethylsiloxane copolymer, polyether-modified polysiloxanes, organo-modified polysiloxanes, and combinations thereof.

10. The method of claim 6, wherein the step of providing an ink comprises providing an ink with a dopant-silicate carrier that is end-capped with an end-capping group, wherein the weight percent of the end-capping group in the end-capped dopant-silicate carrier is up to about 10% of the dopant-silicate carrier.

11. The method of claim 1, wherein the step of applying the ink to the semiconductor substrate comprises applying the ink to the semiconductor substrate in a pattern having a feature with at least one dimension of less than about 200 μm.

12. The method of claim 11, wherein the step of applying the ink to the semiconductor substrate in a pattern having a feature with at least one dimension of less than about 200 μm comprises applying the ink to the semiconductor substrate in a pattern having a feature with at least one dimension of less than about 100 μm.

13. The method of claim 12, wherein the step of applying the ink to the semiconductor substrate in a pattern having a feature with at least one dimension of less than about 100 μm comprises applying the ink to the semiconductor substrate in a pattern having a feature with at least one dimension of less than about 20 μm.

14. A dopant-comprising ink comprising:
a dopant-silicate carrier; and
a solvent,
wherein the dopant-comprising ink has a spreading factor that is in a range of from about 1.5 to about 6.

15. The dopant-comprising ink of claim 14, wherein the dopant-silicate carrier comprises a boron-silicate carrier or a phosphorous-silicate carrier.

16. The dopant-comprising ink of claim 14, further comprising a spread-minimizing additive.

17. The dopant-comprising ink of claim 16, wherein the spread-minimizing additive comprises an additive selected from the group consisting of isostearic acid, polypropylene oxide, vinylmethylsiloxane-dimethylsiloxane copolymer, polyether-modified polysiloxanes, organo-modified polysiloxanes, and combinations thereof.

18. The dopant-comprising ink of claim 14, wherein the solvent comprises at least one alcohol.

19. The dopant-comprising ink of claim 14, further comprising a functional additive selected from the group consisting of dispersants, surfactants, polymerization inhibitors, wetting agents, antifoaming agents, detergents and other surface-tension modifiers, flame retardants, pigments, plasticizers, thickeners, viscosity modifiers, rheology modifiers, and mixtures thereof.

20. The dopant-comprising ink of claim 14, further comprising an additional solvent with a boiling point in the range of about 50° C. to about 250° C.

21. The dopant-comprising ink of claim 14, wherein the dopant-silicate carrier is end-capped with an end-capping alkylsilyl group, an end-capping arylsilyl group, or a combination of end-capping alkylsilyl and end-capping arylsilyl groups.

22. The dopant-comprising ink of claim 21, wherein the weight percent of the end-capping group or groups of the end-capped dopant-silicate carrier is up to about 10% of the dopant-silicate carrier is end-capped.

23. The dopant-comprising ink of claim 21, wherein the end-capped dopant-silicate carrier comprises an end-capped boron-silicate carrier or an end-capped phosphorous-silicate carrier.

24. The dopant-comprising ink of claim 21, further comprising a spread-minimizing additive, wherein the spread-minimizing additive comprises an additive selected from the group consisting of isostearic acid, polypropylene oxide, vinylmethylsiloxane-dimethylsiloxane copolymer, polyether-modified polysiloxanes, organo-modified polysiloxanes, and combinations thereof.

25. The dopant-comprising ink of claim 21, wherein the solvent comprises at least one alcohol.

26. The dopant-comprising ink of claim 21 further comprising a functional additive selected from the group consisting of dispersants, surfactants, polymerization inhibitors, wetting agents, antifoaming agents, detergents and other surface-tension modifiers, flame retardants, pigments, plasticizers, thickeners, viscosity modifiers, rheology modifiers, and mixtures thereof.

27. The dopant-comprising ink of claim 21, further comprising an additional solvent with a boiling point in the range of about 50° C. to about 250° C.

28. A dopant-comprising ink comprising:
an end-capped dopant-silicate carrier; and
a solvent.

29. The dopant-comprising ink of claim 28, wherein the end-capped dopant-silicate carrier comprises an end-capped boron-silicate carrier or an end-capped phosphorous-silicate carrier

30. The dopant-comprising ink of claim 28, wherein the solvent comprises at least one alcohol.

31. The dopant-comprising ink of claim 28, further comprising a functional additive selected from the group consisting of dispersants, surfactants, polymerization inhibitors, wetting agents, antifoaming agents, detergents and other surface-tension modifiers, flame retardants, pigments, plasticizers, thickeners, viscosity modifiers, rheology modifiers, and mixtures thereof.

32. The dopant-comprising ink of claim 28, further comprising an additional solvent with a boiling point in the range of about 50° C. to about 250° C.

33. The dopant-comprising ink of claim 28, wherein the end-capped dopant-silicate carrier is end-capped with an end-capping alkylsilyl group, an end-capping arylsilyl group, or a combination of end-capping alkylsilyl and end-capping arylsilyl groups.

34. The dopant-comprising ink of claim 33, wherein the weight percent of the end-capping group or groups of the end-capped dopant-silicate carrier is up to about 10% of the dopant-silicate carrier is end-capped.
